(19) United States
(12) Patent Application Publication
(10) Pub. No.: US 2009/0267871 A1
(43) Pub. Date: Oct. 29, 2009

(54) SWITCHING CIRCUIT, PIXEL DRIVE CIRCUIT, AND SAMPLE-AND-HOLD CIRCUIT

(75) Inventor: Takahisa Tanabe, Saitama (JP)

Correspondence Address: DRINKER BIDDLE & REATH (DC), 1500 K STREET, N.W., SUITE 1100, WASHINGTON, DC, 20005-1209, US

(73) Assignee: Pioneer Corporation, Meguro-ku (JP)

(21) Appl. No.: 12/440,349

(22) PCT Filed: Aug. 27, 2007
(86) PCT No.: PCT/JP2007/066525

§ 371 Date: Mar. 6, 2009

(30) Foreign Application Priority Data
Sep. 12, 2006 (JP) 2006-246431

(51) Int. Cl. G09G 3/20; G11C 27/02

(52) U.S. Cl. 345/55; 327/94

(57) ABSTRACT

At least two FETs are provided having controlled terminals serially connected to each other between an input terminal and an output terminal. The FET are alternatingly driven to “off” via the controlled terminals when an “off” command is present, and the FETs are simultaneously driven to “on” via the controlled terminals when an “on” command is present.

### TECHNICAL FIELD

The present invention relates to a switching circuit that uses field effect transistors (FETs), a pixel drive circuit, and a sample-and-hold circuit, and more particularly relates to a technology for suppressing variation of a gate threshold voltage caused by gate stress in the FETs.

### BACKGROUND ART

TFTs (thin film transistors), which are used as elements for driving pixels in organic EL displays, liquid crystal displays, and other displays, are one type of FET; and are formed from amorphous silicon (a-Si), an organic semiconductor, or another appropriate material. It is known in the art that stress is generated and the gate threshold voltage Vth varies when a fixed voltage is continually applied to the gate of the TFT element.

FIG. 1 shows the drain current (I_{D})-gate voltage (V_{GE}) characteristics before and after a positive voltage has been applied, in a case in which the positive voltage is continuously applied between a gate and a source of an enhancement-type P-channel TFT. P1 shows the initial I_{D}-V_{GE} characteristics of the P-channel TFT before the positive voltage has been applied, and P2 shows the I_{D}-V_{GE} characteristics after the positive voltage has been applied. Specifically, the diagram shows that when gate stress from a positive voltage is continuously applied between the gate and source of the P-channel TFT, the gate threshold voltage Vth varies in the positive direction. When gate stress from a negative voltage is continuously applied between the gate and the source, Vth varies in the negative direction, which is the reverse of the case described above.

It is known that the rate of Vth variation increases as the voltage applied to the gate increases, and that Vth, which varies according to the gate bias, returns to the initial characteristics before Vth varies as a result of bias of a polarity that is the reverse of the original bias polarity, or 0 V being continuously applied between the gate and the source.

A shift register is disclosed in Patent Document 1, wherein a voltage corresponding to the Vth variation is applied to a back gate, thereby compensating for the Vth variation.

Patent Document 1: Japanese Laid-open Patent Publication No. 2006-174294

### DISCLOSURE OF THE INVENTION

### Problems the Invention is Intended to Solve

Consideration will now be given to a case in which a TFT having the above characteristics is used in a switching circuit. When the TFT, which constitutes a switching element, is supposed to drive the switching circuit to the “off” state, a positive voltage (or a negative voltage) is applied to the gate G, and the TFT is driven in a turn-off state. The voltage continues to be applied to the gate of the TFT as long as the switching circuit is kept in the “off” state, which results in gate stress and Vth variation. When Vth variation occurs in the switching circuit, a complete “off” state is not attained, even when the drive state of the switching circuit is supposed to be “off,” a leak current flows, and, if Vth variation progresses further, a condition wherein an “off” state cannot be attained at all may arise. One method used to circumvent such an event involves applying an extremely large positive voltage (or negative voltage) during the “off” period of the switching circuit; however, such a method is not effective because, as described above, the progress of Vth variation is thereby accelerated.

With the foregoing points in view, it is an object of the present invention to provide a switching circuit having a TFT that does not cause the threshold voltage Vth to vary, and a pixel drive circuit and sample-and-hold circuit in which the switching circuit is used.

### Means for Solving the Problems

The switching circuit of the present invention is a switching circuit for relaying an input signal from an input terminal to an output terminal in response to an “on” command, and for halting relaying of the input signal from the input terminal to the output terminal in response to an “off” command; characterized in comprising at least two FETs having controlled terminals serially connected to each other between the input terminal and the output terminal, and a drive portion for alternatingly driving the FETs to “off” via controlled terminals of the FETs when the “off” command is present, and for driving simultaneously driving the FETs to “on” via the controlled terminals when the “on” command is present.

The pixel drive circuit of the present invention is a pixel drive circuit of a display panel in which a plurality of light-emitting elements as pixels are disposed at intersections of a plurality of data lines and a plurality of scan lines; characterized in comprising light-emission drive means for supplying to the light-emitting elements a light-emission drive current corresponding to a data pulse supplied via the data lines, and a switching circuit for relaying the data pulse from the data lines to the light-emission drive means in response to an “on” command supplied via the scan lines, and for halting the relaying of the data pulse from the data lines to the light-emission drive means in response to an “off” command supplied via the scan lines. The switching circuit has at least two FETs having controlled terminals serially connected to each other between the data lines and the light-emission drive means, and has a drive portion for alternatingly driving the FETs to “off” via the controlled terminals of the FETs when the “off” command is present, and for simultaneously driving the FETs to “on” via the controlled terminals when the “on” command is present. The scan lines have at least two scan line electrodes corresponding to each of the FETs.

The sample-and-hold circuit of the present invention is a sample-and-hold circuit comprising signal holding means for holding an input signal input from an input terminal, outputting means for outputting from an output terminal an input signal held in the signal holding means, and a switching circuit for relaying the input signal from the input terminal to the signal holding means in response to an “on” command, and for halting the relaying of the input signal from the input terminal to the signal holding means in response to an “off” command. The sample-and-hold circuit is characterized in that the switching circuit has at least two FETs having controlled terminals serially connected to each other between the input terminal and the signal holding means, and a drive portion for alternatingly driving the FETs to “off” via the controlled terminals of the FETs when the “off” command is present, and for simultaneously driving the FETs to “on” via the controlled terminals when the “on” command is present.

### BRIEF DESCRIPTION OF THE DRAWINGS

FIG. 1 is a drawing showing drain current gate voltage characteristics of a P-channel TFT before and after gate stress occurs;

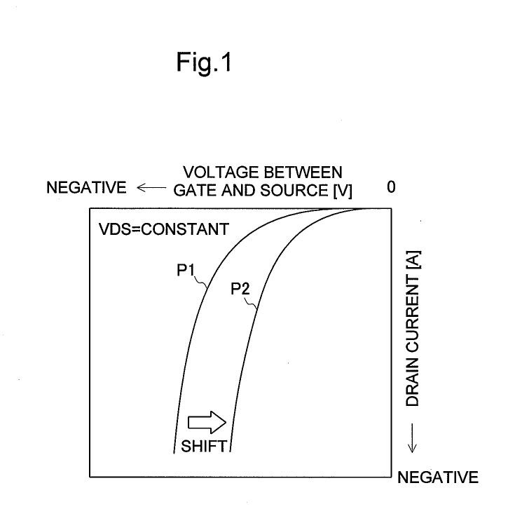

FIG. 2 is a drawing showing a schematic configuration of an EL display device constituting a pixel drive circuit according to an embodiment of the present invention;

FIG. 3 is a drawing showing a configuration of a pixel drive circuit according to an embodiment of the present invention;

FIG. 4 is a drawing showing one example of a timing chart of the scanning pulse signal that is supplied to the pixel drive circuit according to an embodiment of the present invention;

FIG. 5 is a drawing showing another example of a timing chart of the scanning pulse signal that is supplied to the pixel drive circuit according to an embodiment of the present invention;

FIG. 6 is a drawing showing another configuration of the pixel drive circuit according to an embodiment of the present invention;

FIG. 7 is a drawing showing a schematic configuration of a sample-and-hold circuit according to an embodiment of the present invention;

FIG. 8 is a drawing showing one example of a timing chart of the driving pulse signal supplied to the sample-and-hold circuit according to an embodiment of the present invention; and

FIG. 9 is a drawing showing another example of a timing chart of the driving pulse signal supplied to the sample-and-hold circuit according to an embodiment of the present invention.

### BEST MODE FOR CARRYING OUT THE INVENTION

The preferred embodiments of the present invention are described below with reference to the attached drawings. In the drawings shown hereinafter, structural elements and portions that are substantially the same or equivalent are assigned the same reference numeral.

### First Embodiment

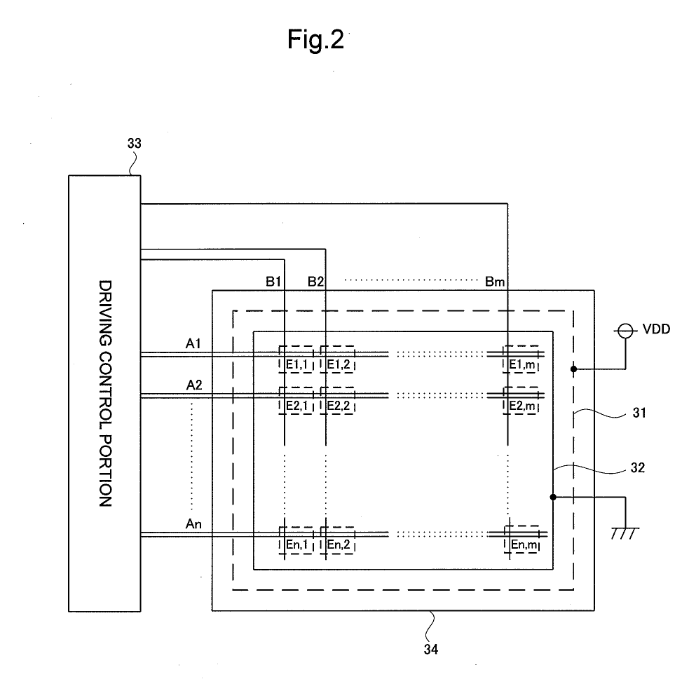

According to a first embodiment of the present invention, a switching circuit is applied in a pixel drive circuit of an active matrix drive type. FIG. 2 is a drawing showing a schematic configuration of an active-matrix-drive EL display device. As shown in FIG. 2, the EL display device is comprised of a display panel 34, and a drive control portion 33 for driving the display panel 34 in response to a video signal. The display panel 34 is provided with an anode power source line 31, a cathode power source line 32, scan lines A₁ to Aₙ as n horizontal scan lines forming pixel cells, and m data lines B₁ to Bₘ that are arranged to intersect each of the scan lines. A drive voltage V_{DD} is applied to the anode power source line 31, and a ground potential GND is applied to the cathode power source line 32. Pixel drive circuits E_{1,1} to E_{n,m} are formed at each of the intersections of the scan lines A₁ to Aₙ and the data lines B₁ to Bₘ in the display panel 34. The pixel drive circuits E_{1,1} to E_{n,m} are comprised of a TFT or other circuit comprising amorphous silicon or an organic semiconductor formed on a glass substrate constituting the display panel 34.

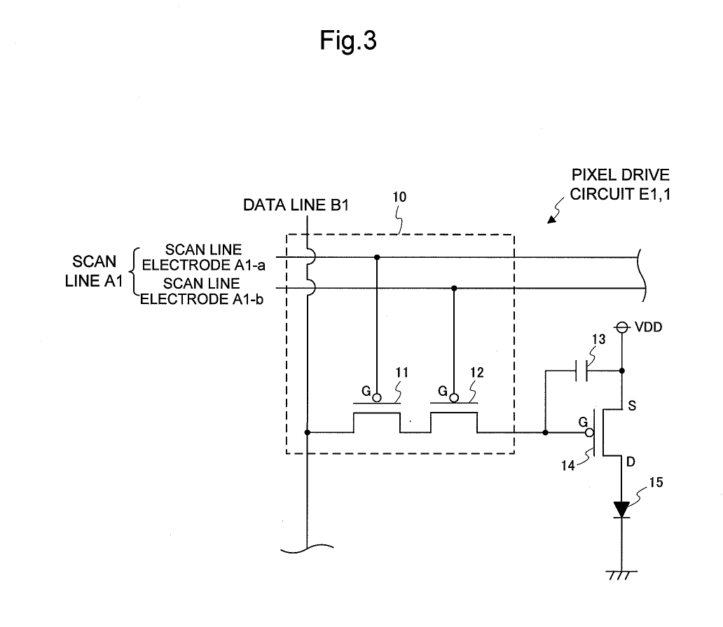

FIG. 3 is a drawing showing the configuration of the interior of the pixel drive circuit E_{1,1}, to which the switching circuit 10 of the present invention is applied, formed at the intersection of one scan line A₁ and one data line B₁. As shown in FIG. 3, the scan line A₁ is comprised of two scan line electrodes A₁₋ₐ and A_{1-b}. A gate G, which is a controlled terminal of two P-channel FETs 11, 12 that are serially connected and are used for selecting a scan line, is connected to each of the scan line electrodes A₁₋ₐ and A_{1-b}. The data line B₁ is connected to one of either the source or the drain of the former-stage selecting FET 11 that forms the input terminal of the switching circuit 10, and the gate of a P-channel FET 14 for driving the emission of light is connected to one of either the source or the drain of the latter-stage selecting FET 12 that forms the output terminal of the switching circuit 10. The drive voltage V_{DD} is applied to a source S of the light-emission drive FET 14 via the anode power source line 31, and a capacitor 13 is connected between the gate G and the source S. An anode terminal of an organic EL element 15 is connected to a drain D of the light-emission drive FET 14. The ground potential GND is applied to a cathode terminal of the organic EL element via the cathode power source line 32. The other pixel drive circuits besides the pixel drive circuit E_{1,1} have a configuration that is the same as the one described above. The source and drain of the FETs used in the switching circuit of the present invention are symmetrical to each other, and have no structural difference; for example, in the case of a P-channel FET, the high voltage side functions as the source and the low voltage side functions as the drain.

The drive control portion 33 has a scan line drive circuit and a data line drive circuit. The drive control portion 33 applies a scanning pulse signal to each of the scan lines A₁ to Aₙ of the display panel 34, and, in synchronization with the timing at which the scanning pulse signal is applied, generates a pixel data pulse signal that corresponds to the input video signal corresponding to each of the horizontal scan lines, and applies the pixel data pulse signal to each of the data lines B₁ to Bₘ. Each of the pixel data pulse signals has a pulse voltage corresponding to the brightness level represented by each of the input video signals. In this case, applying the scanning pulse signal causes each of the pixel drive circuits connected on the selected scan lines to become the target of the writing of pixel data. The selecting FETs 11, 12 of the pixel drive circuits that have become pixel data write targets change to an “on” state in response to the scanning pulse signal, and the pixel data pulse signal supplied via the data line B₁ is applied to the gate G and the capacitor 13 of the light-emission drive FET 14. A method for driving the selecting FETs 11, 12 will now be described. The light-emission drive FET 14 supplies a light-emission drive current corresponding to the pulse voltage of the pixel data pulse signal to the organic EL element 15. The organic EL element 15 emits light of a brightness corresponding to the light-emission drive current. The capacitor 13 is charged by the pulse voltage of the pixel data pulse signal. This charging action causes a voltage corresponding to the brightness level represented by the input video signal to be held in the capacitor 13, and so-called “pixel data writing” is performed. On being released from being pixel data writing targets, the selecting FETs 11, 12 change to an “off” state, and the supplying of the pixel data pulse signal to the gate G of the light-emission drive FET 14 is halted. However, the voltage held in the capacitor 13 even during this interval continues to bias the gate G of the light-emission drive FET 14; therefore, the FET 14 continuously passes a light-emission drive current to the organic EL element 15.

As described above, the selecting FETs of the pixel drive circuit are two serially connected P-channel FETs 11, 12; therefore, when both are in the “on” state, the pixel data pulse signal is applied both to the gate of the light-emission drive FET 14 and to the capacitor 13. Specifically, as long as at least one of the selecting FETs changes to the “off” state, then even if the other is in the “on” state, the pixel data pulse signal will not be applied to the gate G of the light-emission drive FET 14 or to the capacitor 13. Accordingly, the drive control portion 33 performs the drive control of the selecting FETs as described below, thereby eliminating gate stress on the selecting FETs, and suppressing Vth variation.

Specifically, in order to maintain the “off” state of the selecting FET in a conventional pixel drive circuit during a period in which the scan lines are not selected, the gate of the selecting FET is fixed at a high-level (or low-level) scanning pulse voltage, whereupon gate stress occurs, and Vth varies. When Vth variation occurs in the selecting FET of the pixel drive circuit, the leak between source and drain increases during the period in which the scan lines are not selected, the level of the voltage of the pixel data pulse signal held in the capacitor varies, and a risk is presented that the quality of the image will dramatically deteriorate. Contrary, according to the present invention, scanning pulse signals of opposite phases are applied to the gates of the serially connected FETs during the period when the scan line is not being selected, and the phase is inverted at every frame, thereby eliminating gate stress on the selecting FETs and preventing Vth from varying.

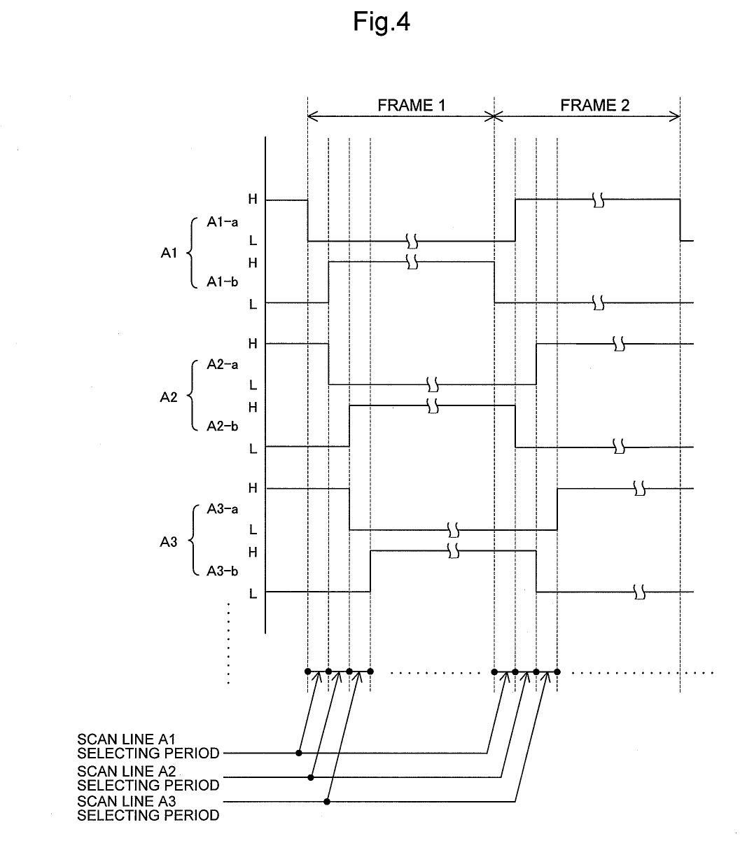

FIG. 4 shows one example of a timing chart of the scanning pulse signal that is supplied by the drive control portion 33 to each of the scan lines A₁ to Aₙ formed on the display panel 34. The drive control portion 33 applies a predetermined scanning pulse signal to each of the scan lines A₁ to Aₙ in sequence within one frame display period, whereby the pixel drive circuits connected to the scan lines become pixel data writing targets. As previously described, the selecting FETs of the pixel drive circuits are two serially connected P-channel FETs 11, 12; therefore, when a low-level scanning pulse voltage is applied to the gates G of the selecting FETs 11, 12 at the same time, both selecting FETs 11, 12 change to the “on” state, and the pixel drive circuits connected to the scan lines are selected as pixel data writing targets. Specifically, there is provided a period during which the drive control portion 33 simultaneously applies a low-level scanning pulse signal to both of two scan line electrodes A₁₋ₐ, A_{1-b} to Aₙ₋ₐ, A_{n-b} that constitute the scan lines A₁ to Aₙ. This period is used as the scan line selecting period, and within one frame period the scan lines A₁ to Aₙ are selected in sequence. The drive control portion 33 applies a pixel data pulse signal via a data line to the pixel drive circuit on the selected scan line, whereby one screen (frame) is formed. The low-level scanning pulse voltage that is applied to the scan lines is a voltage that is sufficiently lower than the voltage obtained by adding the lowest voltage among the data signals to the gate threshold voltage Vth of the selecting FET.

As described above, in a case in which at least one of the selecting FETs 11, 12 is in the “off” state, an input terminal and an output terminal of the switching circuit 10 change to a blocked state, and the pixel data pulse signal will not be applied to the gate G of the light-emission drive FET 14 and the capacitor 13. As shown in FIG. 4, during the period in which the scan lines are not selected, the drive control portion 33 applies a high-level scanning pulse voltage and a low-level scanning pulse voltage to each of the gates G of the selecting FETs via two scan line electrodes A₁₋ₐ and A_{1-b}, in order for at least one of the selecting FETs 11, 12 to change to the “off” state. The drive control portion 33 also inverts the voltage level of the scanning pulse signal in the period in which the scan lines are not selected for each frame.

Specifically, during the period in which the scan lines are not selected, the drive control portion 33 applies a high-level scanning pulse voltage to one of the selecting FETs, and applies a low-level scanning pulse voltage to the other selecting FET, whereby a nonselection state is brought about. In the period of the next frame in which the scan lines are not selected, the polarities of the scanning pulse voltages are both inverted and a nonselection state is brought about. As a result, the gates G of the selecting FETs will not be fixed at a high-level scanning pulse voltage during the nonselection period in order to keep the selecting FETs in the “off” state. The scanning pulse voltages are similarly applied for the other scan lines A₂ to Aₙ.

It is preferred for the absolute value of the difference between the average voltage of the data signal and the voltage level of the high-level scanning pulse signal applied to the gates G of the selecting FETs and carrying the “off” command for the selecting FETs 11,12 to be substantially equivalent to the absolute value of the difference between the average voltage of the data signal and the voltage level of the low-level scanning pulse signal carrying the “on” command, and for the polarities to be opposite one another. Specifically, it is preferable for the absolute value of the average voltage between the gate and the source at the time the high-level scanning pulse is applied to be substantially equivalent to the absolute value of the average voltage between the gate and the source at the time the low-level scanning pulse is applied, and for the polarities to be opposite one another. Such an arrangement allows the average voltage applied between the gate and the source of the selecting FETs to be substantially zero; therefore, gate stress can be eliminated, and variation of the Vth of the selecting FETs can be suppressed.

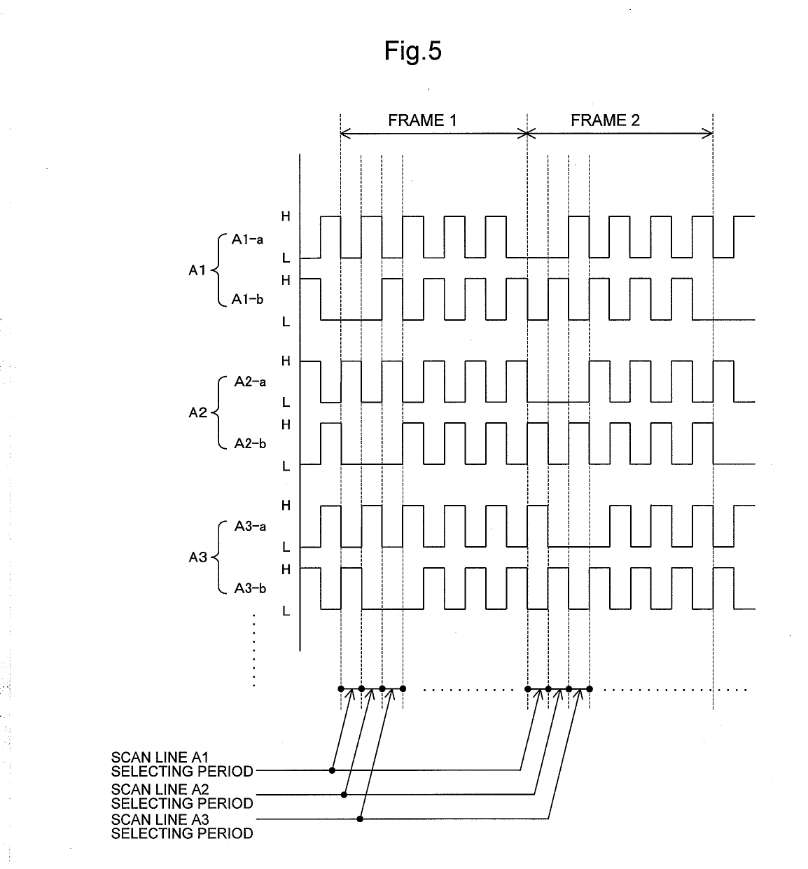

In the above-described embodiment, during the period in which the scan lines are not selected, at least one of the selecting FETs is made in the “off” state, and the voltage level of the scanning pulse signal is inverted in each frame. However, as shown in FIG. 5, during the period in which the scan lines are not selected, the voltage level of the scanning pulse signal may be inverted a plurality of times within a frame so that at least one of the selecting FETs will change to the “off’ state. Specifically, a high-level scanning pulse voltage is applied to one of the selecting FETs, and a low-level scanning pulse voltage is applied to the other selecting FET, thereby bringing about a nonselection state, and the polarities of both of the scanning pulse voltages will be repeatedly inverted within the period in which the scan lines are not selected in the frame. This drive method also enables the nonselection state to be maintained and the gate stress associated with the selecting FETs to be eliminated.

In the above-described embodiment, an example is described in which the selecting FETs and the light-emission drive FET are constructed as P-channel FETs; however, N-channel FETs may also be used. In this case, the scanning pulse voltage applied to the gate of the selecting FET may be of a polarity opposite to that of the case in which P-channel FETs are used.

The switching circuit of the above described embodiment is of a configuration in which two selecting FETs are serially connected; however, three or more FETs may also be serially connected.

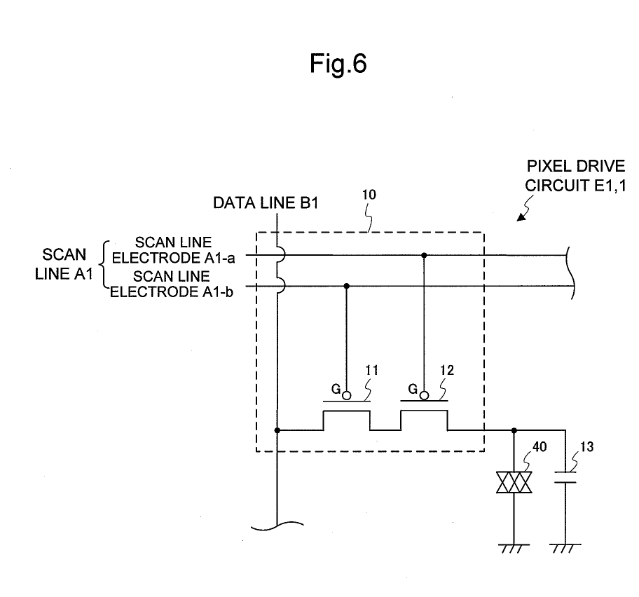

In the above-described embodiment, an example is described in which the switching element of the present invention is applied to a pixel drive circuit that performs light-emission control of the organic EL element; however, the switching element may also be applied to a pixel drive circuit for driving a liquid crystal panel. FIG. 6 is a schematic drawing of a pixel drive circuit for driving a liquid crystal pixel 40 secured to a transparent electrode. The operating principle is substantially the same as in the case wherein the organic EL is used, but differs from the organic EL case in that the light-emission drive FET 15 is not provided. Specifically, in a case in which the selecting FETs 11, 12 associated with the liquid crystal pixel 40 are changed to the “on” state at the same time, a pixel data pulse signal corresponding to the brightness level is applied via the data lines, and the pixel data is written. As in the above embodiment, the voltage level of the scanning pulse signal is inverted each frame so that at least one of the selecting FETs will change to the “off” state during the period in which the scan lines are not selected, and a high-level scanning pulse voltage and a low-level scanning pulse voltage are alternatingly applied to the gates G of the selecting FETs, thereby suppressing Vth variation.

As is evident from the above description, the switching circuit of the present invention that constitutes a selecting FET of a pixel drive circuit includes two FETs serially connected between the input terminal and output terminal. During the period in which the scan lines are not selected, the nonselection state is maintained while the level of the drive voltages applied to each of the gates is inverted so that at least one of the FETs will change to the “off” state; therefore, the gates G of the selecting FETs are not fixed at a high-level (or a low-level) voltage in order to maintain the nonselection state, gate stress is eliminated, and Vth variation is suppressed.

### Second Embodiment

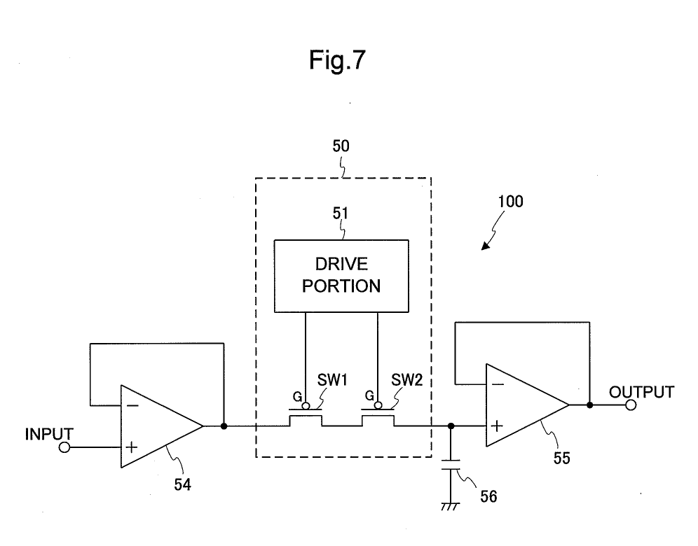

A second embodiment of the present invention will now be described with reference to the accompanying drawings. In the second embodiment, the switching circuit of the present invention is applied to a sample-and-hold circuit. FIG. 7 is a circuit block diagram of a sample-and-hold circuit 100 to which a switching circuit 50 of the present invention is applied. The sample-and-hold circuit 100 is comprised of a TFT or other circuit comprising amorphous silicon or an organic semiconductor formed on a glass substrate, and is used, e.g., in a drive circuit for generating a light-emission drive signal for display devices such as organic EL displays.

The sample-and-hold circuit 100 comprises two operational amplifiers 54, 55 that constitute a voltage follower, a capacitor 56 connected between a noninverting input (+) terminal of the operational amplifier 55 of the latter stage and a Gnd, and the switching circuit 50 serially connected between an output terminal of the operational amplifier 54 of the former stage and the noninverting input (+) terminal of the latter-stage operational amplifier 55.

A sampling voltage input to a noninverting input (+) terminal of the former-stage operational amplifier 54 is output directly to the output terminal. Specifically, the operational amplifier 54 outputs from the output terminal a voltage of the same magnitude as the sampling voltage input to the input terminal, and an impedance conversion is performed between the inputting and outputting, whereby the operational amplifier 54 functions as a buffer for stabilizing the input signal (sampling voltage). The sampling voltage of the operational amplifier 54 that is output from the output terminal is applied to the noninverting input (+) terminal of the operational amplifier 55 and the capacitor 56 when the drive state of the switching circuit 50 is the “on” state. The latter-stage operational amplifier 55, as with the former-stage operational amplifier 54, outputs from the output terminal a voltage of the same magnitude as the sampling voltage input to the noninverting input (+) terminal. The capacitor 56 is charged by the sampling voltage. The charging action causes the sampling voltage to be held in the capacitor 56, and so-called “sampling and holding” is performed. When the drive state of the switching circuit 50 is changed to the “off” state, the supplying of the sampling voltage from the operational amplifier 54 to the operational amplifier 55 will be blocked. However, the sampling voltage still held in the capacitor 56 will be applied to the noninverting input (+) terminal of the operational amplifier 55 during this time as well, and therefore the operational amplifier 55 will continue to output the sampling voltage. Specifically, the sample-and-hold circuit 100 controls the actions of refreshing and holding the sampling voltage depending upon whether the drive state of the switching circuit is “on” or “off.”

As shown in FIG. 7, the switching circuit 50 comprises switching elements SW1 and SW2 comprised of P-channel FETs, and a drive portion 51 for generating a driving pulse signal in order to drive the switching elements. The switching elements SW1 and SW2 are serially connected; a source S of the former-stage switching element SW1, which is the input terminal of the switching circuit 50, is connected to the output terminal of the operational amplifier 54; and a drain D of the latter-stage switching element SW2, which is the output terminal of the switching circuit 50, is connected to the noninverting input (+) terminal of the operational amplifier 55 and to the capacitor 56. Gates G, which are terminals controlled by the switching elements SW1 and SW2, are each connected to the drive portion 51.

The switching elements SW1 and SW2 are changed to the “on” state as a result of a negative voltage whose absolute value is greater than a gate threshold voltage Vth being applied between the gate and the source from the drive portion 51, and are changed to the “off” state as a result of 0 V or a positive voltage being applied between the gate and the source. Since the two switching elements are serially connected, the sampling voltage output from the output terminal of the former-stage operational amplifier 54 will not be transmitted to the latter-stage operational amplifier 55 if the switching elements SW1 and SW2 are in the “on” state at the same time. Specifically, as long as at least one of the switching elements is in the “off” state, the switching circuit 50 will be in the “off” state (blocked state) even if the other switching element is in the “on” state. Accordingly, the drive portion 51 drives and controls the switching elements SW1 and SW2 described hereinafter, thereby eliminating gate stress in the switching elements SW1 and SW2 and suppressing Vth variation.

Specifically, in the period that the switching circuit is “off,” the gate of the switching element has conventionally been fixed at a high-level (or a low-level) drive voltage in order to keep the switching element in the “off” state; and this has led to gate stress and Vth variation. When Vth variation occurs in switching elements of a sample-and-hold circuit, leakage between the source and drain increases during the “off” state (blocked state) of the switching circuit, the voltage level of the sampling voltage held in the capacitor varies, and a risk is presented that the appropriate sample and hold action will not be able to occur. In contrast, the present invention is configured so that drive voltages of differing polarities are alternatingly applied to the gates of the serially connected switching elements SW1 and SW2 during the “off” period of the switching circuit 50, thereby eliminating gate stress in the switching elements and ensuring Vth variation does not occur.

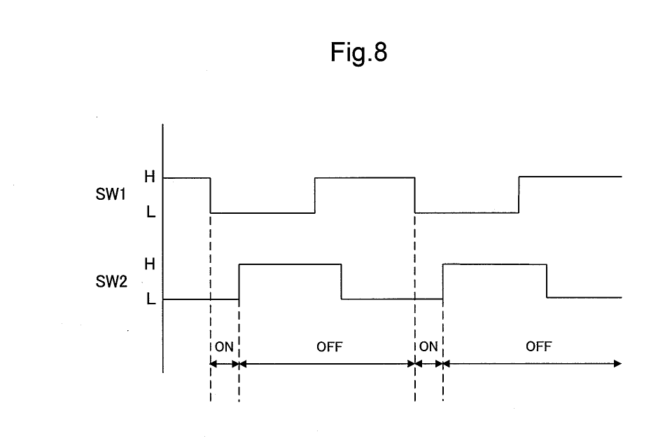

FIG. 8 is a diagram showing one example of a timing chart of the driving pulse signal supplied by the drive portion 51 to the gates G of the switching elements SW1 and SW2. As described above, when the switching elements SW1 and SW2 both change to the “on” state at the same time, the input terminal and the output terminal of the switching circuit 50 will change to a conducting state, and the sampling voltage output from the operational amplifier 54 will be supplied to the operational amplifier 55. Specifically, as shown in FIG. 8, when a low-level voltage is applied to the gates G of the switching elements SW1 and SW2 at the same time, the switching circuit 50 will change to a conducting state. The low-level voltage applied to the switching elements SW1 and SW2 is a voltage that is sufficiently lower than the voltage obtained by adding the lowest-level voltage amongst the sampling voltage to the gate threshold voltage Vth of the switching elements SW1, SW2. Alternatively, as described above, when at least one of the switching elements SW1 and SW2 is in the “off” state, the input terminal and output terminal of the switching circuit 50 will be in the blocked state, and the sampling voltage will be blocked from being supplied from the operational amplifier 54 to the operational amplifier 55. Therefore, during the period in which the switching circuit 50 is to be in the “off” state (blocked state), the drive portion 51 applies a high-level driving voltage and a low-level driving pulse signal to each of the gates G of the switching elements so that at least one of the switching elements SW1 and SW2 will change to the “off” state. The voltage levels of the driving pulse signals are inverted in every predetermined period. Specifically, during the period in which the switching circuit 50 is to be changed to the “off” state (blocked state), the drive portion 51 applies a high-level driving pulse signal to one of the switching elements, and applies a low-level driving pulse signal to the other switching element. The voltage levels of the driving pulse signals are both inverted in a predetermined cycle, thereby keeping the switching circuit 50 in the “off” state (blocked state). As a result, the gates G of the switching elements will not be fixed at the high-level driving voltage needed in order to maintain the “off” state.

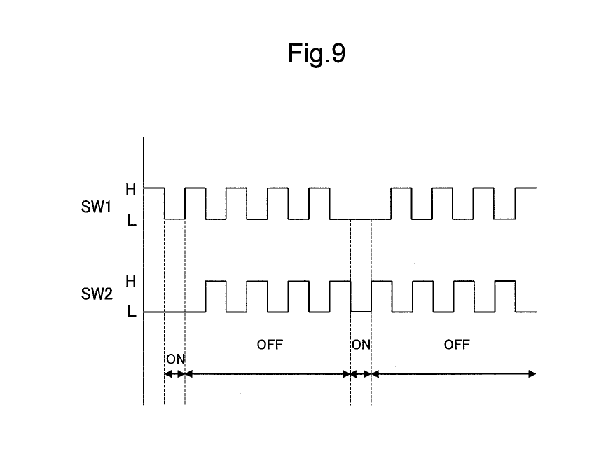

FIG. 9 shows another example of a timing chart of the driving pulse signal supplied to the switching elements SW1 and SW2, in which the inversion cycle of the voltage level of the driving pulse signal during the “off” period of the switching circuit 50 is shorter than that illustrated in FIG. 8.

It is preferred for the absolute value of the difference between the average value of the sampling voltage and the voltage level of the high-level driving pulse signal applied to the gates G of the switching elements and carrying the “off” command for the switching elements SW1 and SW2 to be substantially equivalent to the absolute value of the difference between the average value of the sampling voltage and the voltage level of the low-level driving pulse signal carrying the “on” command, and for the polarities to be opposite one another. Specifically, it is preferable for the absolute value of the average voltage between the gate and the source at the time the high-level driving pulse is applied to be substantially equivalent to the absolute value of the average voltage between the gate and the source at the time the low-level driving pulse is applied, and for the polarities to be opposite one another. During the “off” period of the switching circuit 50 described above, the duty ratio is preferably set at approximately 50% when the voltage level of the driving pulse signal is inverted. This action will enable the average voltage applied to the gates of the switching elements to be substantially zero, allowing gate stress to be eliminated and Vth variation can be suppressed.

The value of the driving voltage applied to the switching elements SW1 and SW2 may be suitably set according to the characteristics of the FETs. When high-level and low-level driving voltages are alternatingly applied during the “off” period of the switching circuit 50, it is typically preferable for the high-level and low-level voltage levels to be set, and the duty ratio to be set at approximately 50%, as described above; however, suitable modifications can be made according to the characteristics of the FETs.

In the above-described embodiment, an example is described in which the switching elements are constructed using P-channel FETs; however, N-channel FETs may also be used. In this case, the driving voltage applied to the gate of the switching element may be of a polarity opposite to that of the case in which P-channel FETs are used.

The switching circuit of the above described embodiment is of a configuration in which two selecting FETs are serially connected; however, three or more FETs may also be serially connected.

1. A video signal display panel, comprising:
a plurality of scan lines and a plurality of data lines;
a switching circuit provided to individual display cells formed at intersections of the scan lines and the data lines, the switching circuit relaying from an input terminal to an output terminal a video data signal supplied from the data lines in response to an “on” command supplied from the scan lines, and halting the relaying from the input terminal to the output terminal in response to an “off” command supplied from the scan lines; and
a display element for producing a display in response to a video data signal from the switching circuit, the display element being provided to each of the display cells; wherein
the switching circuit has at least two field effect transistors (FETs) serially connected between the input terminal and the output terminal; and
the FETs are driven “off” at least once within two frame periods of the video signal when the “off” command is present, and the FETs are simultaneously driven “on” when the “on” command is present.

2. The display panel according to claim 1, wherein each of the scan lines has a pair of scan line electrodes, and in having a scan line drive circuit for supplying two scanning pulse signals to the FETs via the pair of scan line electrodes.

3. The display panel according to claim 2, wherein
the scanning pulse signal has two signal levels of differing polarities; and
the scan line drive circuit supplies scanning pulse signals of mutually opposite phases to the FETs when the “off” command is present, and supplies scanning pulse signals of the same phase to the FETs when the “on” command is present.

4. The display panel according to claim 3, wherein
the scan line drive circuit inverts the phase of the scanning pulse signal for every frame period of the video signal when the “off” command is present.

5. The display panel according to claim 2, wherein
the FETs are formed on a glass substrate for supporting the display panel.

6. The display panel according to claim 1, wherein
the FETs are P-channel transistors.

7. The display panel according to claim 1, wherein
the FETs are N-channel transistors.

8. The display panel according to claim 1, wherein
the FETs comprise amorphous silicon.

9. The display panel according claim 1, wherein
the FETs comprise an organic semiconductor.

10. (canceled)

11. A sample-and-hold circuit, comprising:
a signal holding portion for holding an input signal input from an input terminal;
an outputting portion for outputting from an output terminal an input signal held in the signal holding portion; and
a switching circuit for relaying the input signal from the input terminal to the signal holding portion in response to an “on” command, and for halting the relaying of the input signal from the input terminal to the signal holding portion in response to an “off” command;
wherein the switching circuit includes at least two FETs having controlled terminals serially connected to each other between the input terminal and the signal holding portion, and a drive portion for alternatingly driving the FETs to “off” via the controlled terminals of the FETs when the “off” command is present, and for simultaneously driving the FETs to “on” via the controlled terminals when the “on” command is present.

12. The display panel according to claim 1, wherein the FETs are alternatingly driven a plurality of times “off” within one frame period of the video signal when the “off” command is present, and the FETs are simultaneously driven “on” when the “on” command is present.
